(19) United States
(12) Patent Application Publication
(10) Pub. No.: US 2014/0159104 A1
(43) Pub. Date: Jun. 12, 2014

(54) SEMICONDUCTOR DEVICE

(71) Applicant: SAMSUNG ELECTRO-MECHANICS CO., LTD., Suwon (KR)

(72) Inventors: Jaehoon PARK, Gyunggi-do (KR); In Hyuk SONG, Gyunggi-do (KR); Kee Ju UM, Gyunggi-do (KR); Dong Soo SEO, Gyunggi-do (KR)

(73) Assignee: SAMSUNG ELECTRO-MECHANICS CO., LTD., Suwon (KR)

(21) Appl. No.: 13/829,896

(22) Filed: Mar. 14, 2013

(30) Foreign Application Priority Data
Dec. 6, 2012 (KR) 10-2012-0141453

(51) Int. Cl. H01L 29/739

(52) U.S. Cl. CPC H01L 29/7397
USPC 257/139

(57) ABSTRACT

There is provided a semiconductor device including: a first semiconductor region having a first conductivity; a second semiconductor region having a second conductivity and formed on a surface of the first semiconductor region; a third semiconductor region having the first conductivity and formed on a surface of the second semiconductor region; a gate electrode disposed in a trench that passes through the third semiconductor region in a depth direction and extends to an inside of the second semiconductor region; a first insulation layer formed between the gate electrode and the third semiconductor region; a second insulation layer formed between the gate electrode and the second semiconductor region; and a fourth semiconductor region having the second conductivity and formed in a portion of a surface of the third semiconductor region, wherein a thickness of a portion of the second insulation layer is greater than that of the first insulation layer.

### CROSS-REFERENCE TO RELATED APPLICATIONS

This application claims the priority of Korean Patent Application No. 10-2012-0141453 filed on Dec. 6, 2012, in the Korean Intellectual Property Office, the disclosure of which is incorporated herein by reference.

### BACKGROUND OF THE INVENTION

1. Field of the Invention

The present invention relates to a semiconductor device.

2. Description of the Related Art

In general, power conversion apparatuses have recently been required to have low power consumption. Thus, research into a power semiconductor device, performing a central role in the power conversion apparatus, having low power consumption has been actively undertaken.

In particular, among various types of power semiconductor devices, research into an insulated-gate bipolar transistor (IGBT) is being actively conducted, since the IGBT can reduce an on voltage according to a conductivity modulation effect and induce an increase in current density.

When current density is increased, a saturation voltage V_{ce,sat} may be reduced. Also, when current density is increased, a size of a chip can be decreased while using the same rating current, and thus, chip manufacturing costs can be reduced.

Types of the IGBT include a planar IGBT and a trench IGBT. A planar IGBT has a structure in which a gate electrode is formed along a wafer surface, while a trench IGBT has a structure in which an oxide film is provided in a trench vertically formed downwardly from a wafer surface, and a gate electrode is buried therein.

The trench IGBT includes channels formed in both inner walls of the trench, which may increase channel density, as compared to the planar IGBT. Thus, the trench IGBT can greatly increase a conductivity modulation effect.

Research into a trench IGBT, in particular, is actively being undertaken due to the reasons detailed above.

FIG. 1 is a cross-sectional view of an upper region of a trench IGBT 100.

In this regard, x and y directions of the trench IGBT 100, depicted in FIG. 1 indicate a depth direction and a horizontal direction, respectively.

Referring to FIG. 1, the trench IGBT 100 may include a low concentration n-type semiconductor region 10, a p-type semiconductor region 20 formed on a surface of the n-type semiconductor region 10, and a high concentration n-type semiconductor region 30 formed on a portion of a surface of the p-type semiconductor region 20.

The trench IGBT 100 may further include agate electrode disposed in a trench that passes through the p-type semiconductor region 20 in the depth direction and extends to the low concentration n-type semiconductor region 10.

The trench IGBT 100 may further include an insulation layer 50 formed between the gate electrode 40 and the p-type semiconductor region 20 and between the gate electrode 40 and the low concentration n-type semiconductor region 10.

As shown in FIG. 1, thicknesses of gate electrodes 40-1 and 40-2 and thicknesses of insulation layers 50-1 and 50-2 of the trench IGBT 100 are uniform, irrespective of the depth direction. Thus, a space x₁ between the insulation layers 50-1 and 50-2 formed in upper portions of the gate electrodes 40-1 and 40-2 and a space X₂ between the insulation layers 50-1 and 50-2 formed in lower portions of the gate electrodes 40-1 and 40-2 are identical to each other.

Meanwhile, regarding an actually manufactured trench IGBT, a space between insulation layers formed around gate electrodes is gradually reduced from an upper portion of a trench to a lower portion thereof.

In general, a conductivity modulation effect is closely related to a space between trenches. In particular, the conductivity modulation effect occurs in a lower portion of a trench gate, and thus, the space between trenches must be narrow in the lower portion of the trench gate in order to maximize the conductivity modulation effect.

Therefore, a currently available trench IGBT has a limitation in maximizing the conductivity modulation effect.

### RELATED ART DOCUMENT

(Patent Document 1) Japanese Patent Laid-Open Publication No. 2006-237066

(Patent Document 2) Korean Patent Laid-Open Publication No. 1993-0020724

### SUMMARY OF THE INVENTION

An aspect of the present invention provides a semiconductor device capable of maximizing a conductivity modulation effect.

Another aspect of the present invention provides a semiconductor device having improved current density.

According to an aspect of the present invention, there is provided a semiconductor device including: a first semiconductor region having a first conductivity; a second semiconductor region having a second conductivity and formed on a surface of the first semiconductor region; a third semiconductor region having the first conductivity and formed on a surface of the second semiconductor region; a gate electrode disposed in a trench that passes through the third semiconductor region in a depth direction and extends to an inside of the second semiconductor region; a first insulation layer formed between the gate electrode and the third semiconductor region; a second insulation layer formed between the gate electrode and the second semiconductor region; and a fourth semiconductor region having the second conductivity and formed in a portion of a surface of the third semiconductor region, wherein a thickness of a portion of the second insulation layer is greater than that of the first insulation layer.

The second semiconductor region may further include a buffer layer having the second conductivity and contacting the first semiconductor region, and an impurity concentration in the buffer layer may be higher than that in the second semiconductor region.

The semiconductor device may further include a body layer having the second conductivity and formed on the surface of the second semiconductor region, wherein an upper surface of the body layer having the second conductivity may contact the third semiconductor region, and an impurity concentration in the body layer may be higher than that in the second semiconductor region.

The second insulation layer may have a convex shape.

According to another aspect of the present invention, there is provided a semiconductor device including: a first semiconductor region having a first conductivity; a second semiconductor region having a second conductivity and formed on a surface of the first semiconductor region; a third semiconductor region having the first conductivity and formed on a surface of the second semiconductor region; a plurality of gate electrodes disposed in a plurality of trenches that pass through the third semiconductor region in a depth direction and extend to an inside of the second semiconductor region; a plurality of first insulation layers formed between the gate electrodes and the third semiconductor region; a plurality of second insulation layers formed between the gate electrodes and the second semiconductor region; and a fourth semiconductor region having the second conductivity and formed in a portion of a surface of the third semiconductor region, wherein a space between adjacent second insulation layers is smaller than a space between adjacent first insulation layers.

The second semiconductor region may further include a buffer layer having the second conductivity and contacting the first semiconductor region, and an impurity concentration in the buffer layer may be higher than that in the second semiconductor region.

The semiconductor device may further include a body layer having the second conductivity and formed on a surface of the second semiconductor region, an upper surface of the body layer of the second conductive may contact the third semiconductor region, and an impurity concentration in the body layer may be higher than that in the second semiconductor region.

The space between the adjacent second insulation layers may be 5 μm or less.

According to another aspect of the present invention, there is provided a semiconductor device including: a gate electrode disposed in a trench that passes through a first semiconductor region in a depth direction and extends to an inside of a second semiconductor region; a first insulation layer formed between the gate electrode and the first semiconductor region; and a second insulation layer formed between the gate electrode and the second semiconductor region, wherein a thickness of a portion of the second insulation layer is greater than that of the first insulation layer.

The first semiconductor region may be n-type doped, and the second semiconductor region may be p-type doped.

The first semiconductor region may be p-type doped, and the second semiconductor region may be n-type doped.

According to another aspect of the present invention, there is provided a semiconductor device including: a plurality of gate electrodes disposed in a plurality of trenches that pass through a first semiconductor region in a depth direction and extend to an inside of a second semiconductor region; a plurality of first insulation layers formed between the gate electrodes and the first semiconductor region; and a plurality of second insulation layers formed between the gate electrodes and the second semiconductor region, wherein a space between adjacent second insulation layers is smaller than a space between adjacent first insulation layers.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of an upper region of a trench insulated-gate bipolar transistor (IGBT);

FIG. 2 is a schematic cross-sectional view of an IGBT according to an embodiment of the present invention;

FIG. 3 is an enlarged view of an upper region of the IGBT of FIG. 2; and

FIGS. 4A and 4B are cross-sectional views of an IGBT according to another embodiment of the present invention.

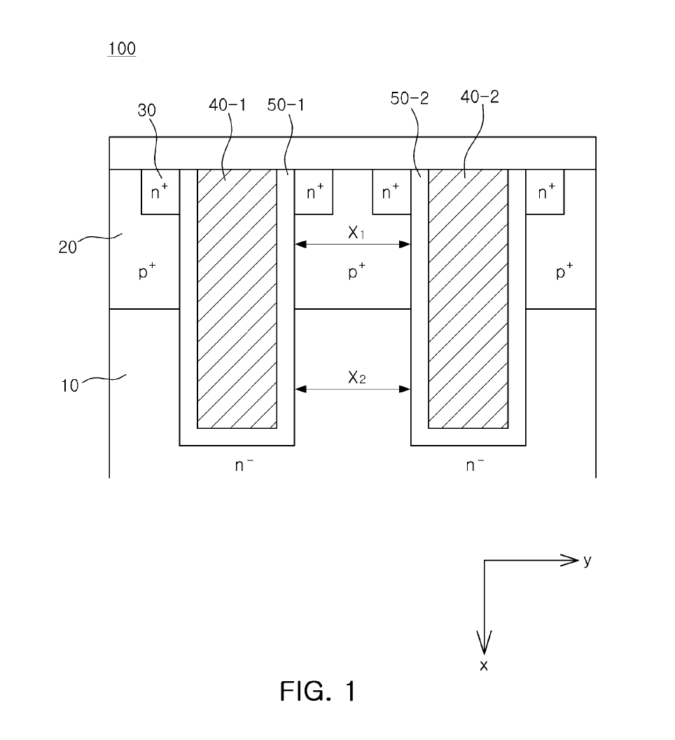

### DETAILED DESCRIPTION OF THE EMBODIMENTS

Hereinafter, embodiments of the present invention will be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements maybe exaggerated for clarity, and the same reference numerals will be used throughout to designate the same or like elements.

A power switch may be configured as one of a power metal oxide semiconductor field effect transistor (MOSFET), an insulated gate bipolar transistor (IGBT), various types of thyristors, and various other switching devices similar thereto. Novel technologies disclosed herein are mostly described with respect to the IGBT. However, embodiments of the present invention disclosed herein are not limited to the IGBT and may be applied to, for example, different types of power switch technology including the power MOSFET and various types of thyristors, in addition to a diode. Moreover, various embodiments of the present invention are illustrated to include specific p-type and n-type regions. However, this applies to devices having types of conductivity opposite to those of various regions disclosed herein.

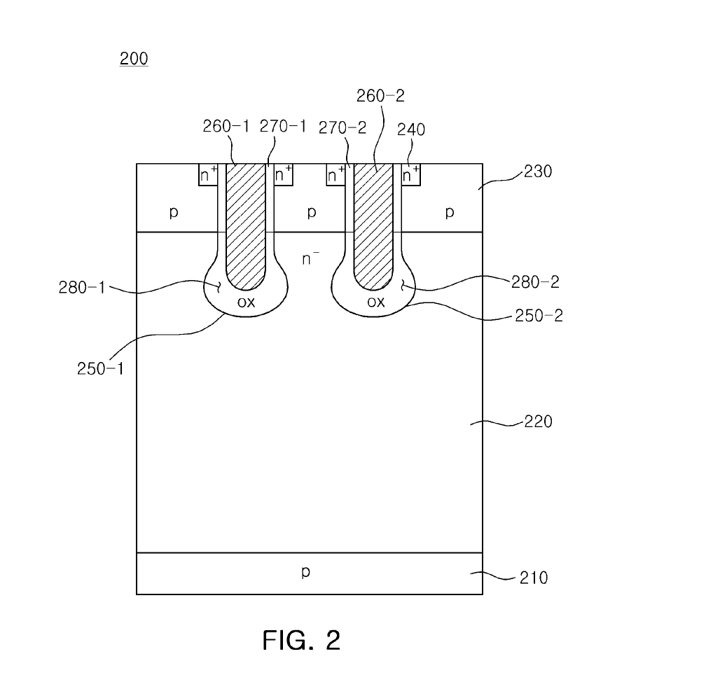

FIG. 2 is a schematic cross-sectional view of an IGBT according to an embodiment of the present invention.

Referring to FIG. 2, an n-type drift layer 220 may be formed on a p-type collector region 210 used as a collector region.

A p-type well region 230 may be formed on an upper surface of the n-type drift layer 220.

The p-type well region 230 may extend on a surface of the n-type drift layer 220 in a depth direction and may be formed to have a stripe shape. The p-type well region 230 may be provided in plural. An n⁺-type source region 240 may be formed in a portion of an upper surface of the p-type well region 230.

The n⁺-type source region 240 maybe provided in plural. The n⁺-type source region 240 may be scattered and formed on a surface of the p-type well region 230.

A plurality of trenches 250-1 and 250-2 may be formed to pass through the p-type well region 230 in the depth direction and extend to the inside of the n-type drift layer 220.

Gate electrodes 260-1 and 260-2 may be formed in the trenches 250-1 and 250-2. The gate electrodes 260-1 and 260-2 may have uniform thicknesses.

Insulation layers may be formed on surfaces of the gate electrodes 260-1 and 260-2 inside the trenches 250-1 and 250-2.

In particular, insulation layers formed between the gate electrodes 260-1 and 260-2 and the p-type well region 230 in the trenches 250-1 and 250-2 are defined as first insulation layers 270-1 and 270-2.

Insulation layers formed between the gate electrodes 260-1 and 260-2 and the n-type drift layer 220 in the trenches 250-1 and 250-2 are defined as second insulation layers 280-1 and 280-2.

Meanwhile, the collector region, the drift layer, the well region, and the source region used herein may be defined as semiconductor regions.

Also, a p-type and an n-type used herein may be defined as a first conductivity or a second conductivity. Meanwhile, the first conductivity and the second conductivity refer to different types of conductivity.

In general, “+” means a state doped to have a high concentration, and “−” means a state doped to have a low concentration.

In the above-described IGBT, a channel region is formed in a side wall portion of the trench 250 of the p-type well region 230. That is, if a voltage higher than a threshold voltage is applied to the gate electrode 260, a conductivity of the side wall portion of the trench 250 within the p-type well region 230 is inverted to form a channel through which an electronic current flows from the n+-type source region 240 to the n-type drift layer 220.

The electronic current acts as a base current of a transistor formed by the p-type well region 230, the n-type drift layer 220, and the p-type collector region 210. In response to the electronic current, a hole current flows from the p-type collector region 210 to an emitter electrode through the n-type drift layer 220 and the p-type well region 230.

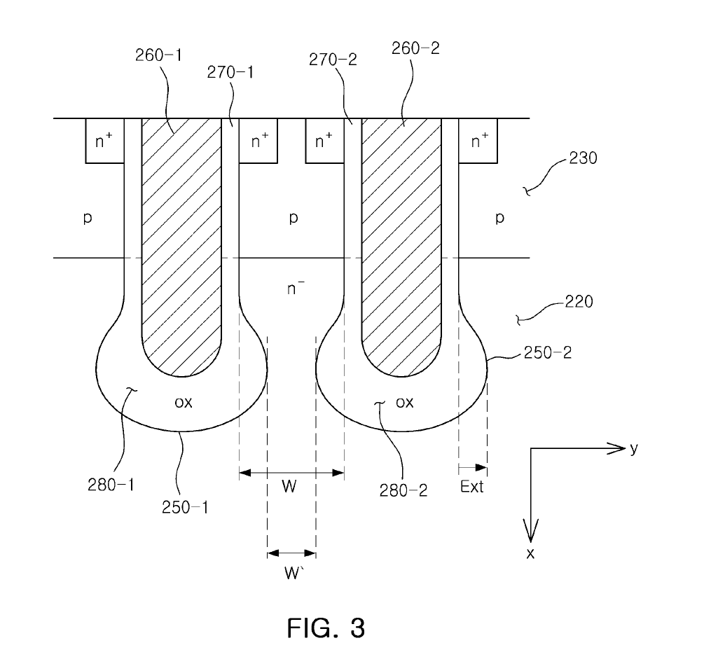

FIG. 3 is an enlarged view of an upper region of the IGBT of FIG. 2.

In this regard, to define directions of a trench IGBT, x and y of FIG. 3 indicate a depth direction and a horizontal direction, respectively.

According to an embodiment of the present invention, the first insulation layers 270-1 and 270-2 have uniform thicknesses, irrespective of depth. Thus, a space W between the adjacent first insulation layers 270-1 and 270-2 is uniform irrespective of depth.

According to an embodiment of the present invention, the second insulation layers 280-1 and 280-2 have different thicknesses according to depth. For example, the thicknesses of the second insulation layers 280-1 and 280-2 may gradually increase in the depth direction during a predetermined section.

As described above, in the case in which the thicknesses of the second insulation layers 280-1 and 280-2 are different according to depth, a space W′ between the adjacent second insulation layers 280-1 and 280-2 may be different according to depth.

Preferably, thicknesses of portions of the second insulation layers 280-1 and 280-2 may be greater than the thicknesses of the first insulation layers 270-1 and 270-2.

Preferably, the space W′ between the adjacent second insulation layers 280-1 and 280-2 may be smaller than the space W between the adjacent first insulation layers 270-1 and 270-2.

The space W′ between the adjacent second insulation layers 280-1 and 280-2 may be preferably smaller.

Preferably, the space W′ between the adjacent second insulation layers 280-1 and 280-2 may be 5 μm or less.

Referring to FIG. 3, the second insulation layers 280-1 and 280-2 are formed to have convex shapes in a downward direction. In the y-axial direction, the thicknesses of the second insulation layers 280-1 and 280-2 may be increased by a predetermined value Ext compared to the thicknesses of the first insulation layers 270-1 and 270-2. In this regard, the space W′ between the adjacent second insulation layers 280-1 and 280-2 may be smaller than the space W between the adjacent first insulation layers 270-1 and 270-2.

As compared with the related art IGBT in which spaces between insulation layers are uniform, the IGBT according to the embodiment of the present invention in which the space W′ between the adjacent second insulation layers 280-1 and 280-2 is smaller than the space W between the adjacent first insulation layers 270-1 and 270-2 may further increase a relative concentration of hole carriers collected in a trench gate lower region.

Due to such an increase in the concentration of hole carriers collected in the trench gate lower region, the IGBT according to the embodiment of the present invention may improve a conductivity modulation effect.

That is, due to a conductivity modulation phenomenon formed in the n-type drift layer 220 of the trench gate lower region, resistance applied to electrons that move from the n+-type source region 240 to the n-type drift layer 220 through the p-type well region 230 may be reduced. Furthermore, a current flowing through the IGTB may increase owing to the conductivity modulation phenomenon.

As described above, when a current density increases, a saturation voltage V_{ce,sat} may be reduced. In addition, when the current density increases, a chip size becomes smaller at the same rating current, and thus chip manufacturing costs may be reduced.

Meanwhile, the thicknesses of the second insulation layers 280-1 and 280-2 of the IGBT according to the embodiment of the present invention increase in the X-axial direction and the y-axial direction, and thus a gate capacitance may be reduced. Thus, a device having a trench gate structure according to an embodiment of the present invention may have an application in a device requiring high current density and high speed switching.

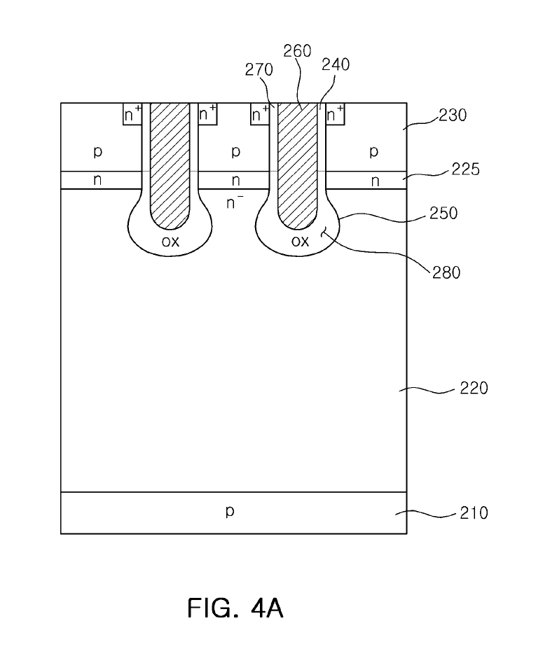

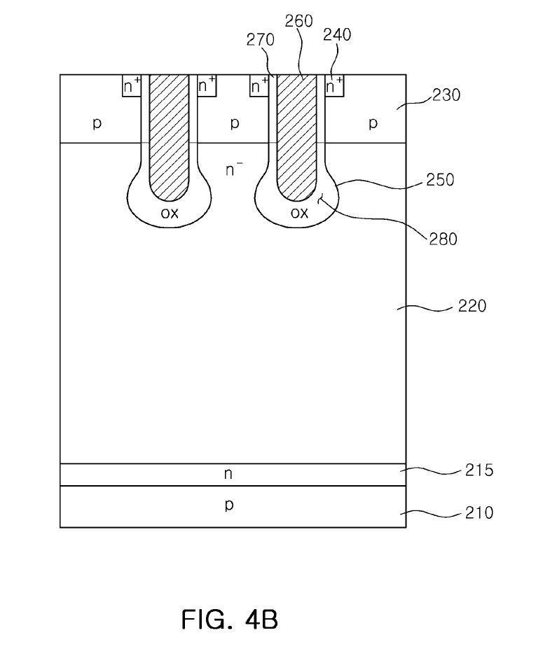

FIGS. 4A and 4B are schematic cross-sectional views of an IGBT according to another embodiment of the present invention. Referring to FIG. 4A, the n-type drift layer 220 may be formed above the p-type collector region 210 used as a collector region. An n-type carrier storage layer 225 may be formed between the n-type drift layer 220 and the p-type well region 230. The n-type carrier storage layer 225 may be formed to contact the p-type well region 230.

The n-type carrier storage layer 225 has an impurity concentration higher than the n-type drift layer 220.

In this case, holes that flow from the n-type drift layer 220 into the p-type well region 230 are restricted from being discharged to an emitter electrode due to exclusion of donor ions of the n-type carrier storage layer 225.

Therefore, according to the above construction, a carrier concentration in a trench lower portion near an emitter increases and an on-voltage is further reduced.

Referring to FIG. 4B, the n-type drift layer 220 may be formed above the p-type collector region 210 used as the collector region. Also, an n-type buffer layer 215 may be formed between the n-type drift layer 220 and the p-type collector region 210.

The n-type buffer layer 215 may provide a field stop function. Thus, as compared to the IGBT having no buffer layer, the n-type drift layer 220 of the IGBT according to the present embodiment may be formed to have a reduced thickness under the same withstand voltage conditions.

Also, the on-voltage of the IGBT according to the present embodiment may be further reduced.

As set forth above, according to embodiments of the present invention, a semiconductor device capable of maximizing a conductivity modulation effect can be provided to a user.

Also, a semiconductor device having improved current density can be provided to a user.

While the present invention has been shown and described in connection with the embodiments, it will be apparent to those skilled in the art that modifications and variations can be made without departing from the spirit and scope of the invention as defined by the appended claims.

What is claimed is:

1. A semiconductor device comprising:
a first semiconductor region having a first conductivity;
a second semiconductor region having a second conductivity and formed on a surface of the first semiconductor region;
a third semiconductor region having the first conductivity and formed on a surface of the second semiconductor region;
a gate electrode disposed in a trench that passes through the third semiconductor region in a depth direction and extends to an inside of the second semiconductor region;
a first insulation layer formed between the gate electrode and the third semiconductor region;
a second insulation layer formed between the gate electrode and the second semiconductor region; and
a fourth semiconductor region having the second conductivity and formed in a portion of a surface of the third semiconductor region,
wherein a thickness of a portion of the second insulation layer is greater than that of the first insulation layer.

2. The semiconductor device of claim 1, wherein the second semiconductor region further includes a buffer layer having the second conductivity and contacting the first semiconductor region, and
an impurity concentration in the buffer layer is higher than that in the second semiconductor region.

3. The semiconductor device of claim 1, further comprising a body layer having the second conductivity and formed on the surface of the second semiconductor region,
wherein an upper surface of the body layer having the second conductivity contacts the third semiconductor region, and
an impurity concentration in the body layer is higher than that in the second semiconductor region.

4. The semiconductor device of claim 1, wherein the second insulation layer has a convex shape.

5. A semiconductor device comprising:
a first semiconductor region having a first conductivity;
a second semiconductor region having a second conductivity and formed on a surface of the first semiconductor region;
a third semiconductor region having the first conductivity and formed on a surface of the second semiconductor region;
a plurality of gate electrodes disposed in a plurality of trenches that pass through the third semiconductor region in a depth direction and extend to an inside of the second semiconductor region;
a plurality of first insulation layers formed between the gate electrodes and the third semiconductor region;
a plurality of second insulation layers formed between the gate electrodes and the second semiconductor region; and
a fourth semiconductor region having the second conductivity and formed in a portion of a surface of the third semiconductor region,
wherein a space between adjacent second insulation layers is smaller than a space between adjacent first insulation layers.

6. The semiconductor device of claim 5, wherein the second semiconductor region further includes a buffer layer having the second conductivity and contacting the first semiconductor region, and
an impurity concentration in the buffer layer is higher than that in the second semiconductor region.

7. The semiconductor device of claim 5, further comprising a body layer having the second conductivity and formed on the surface of the second semiconductor region,
wherein an upper surface of the body layer having the second conductivity contacts the third semiconductor region, and
an impurity concentration in the body layer is higher than that in the second semiconductor region.

8. The semiconductor device of any one of claim 5, wherein the space between the adjacent second insulation layers is 5 μm or less.

9. A semiconductor device comprising:
a gate electrode disposed in a trench that passes through a first semiconductor region in a depth direction and extends to an inside of a second semiconductor region;
a first insulation layer formed between the gate electrode and the first semiconductor region; and
a second insulation layer formed between the gate electrode and the second semiconductor region,
wherein a thickness of a portion of the second insulation layer is greater than that of the first insulation layer.

10. The semiconductor device of claim 9, wherein the first semiconductor region is n-type doped, and
the second semiconductor region is p-type doped.

11. The semiconductor device of claim 9, wherein the first semiconductor region is p-type doped, and
the second semiconductor region is n-type doped.

12. A semiconductor device comprising:
a plurality of gate electrodes disposed in a plurality of trenches that pass through a first semiconductor region in a depth direction and extend to an inside of a second semiconductor region;
a plurality of first insulation layers formed between the gate electrodes and the first semiconductor region; and
a plurality of second insulation layers formed between the gate electrodes and the second semiconductor region,
wherein a space between adjacent second insulation layers is smaller than a space between adjacent first insulation layers.
